(19) United States
(12) Patent Application Publication
(10) Pub. No.: US 2015/0170698 A1
(43) Pub. Date: Jun. 18, 2015

(54) CARBON FILM FORMING APPARATUS, CARBON FILM FORMING METHOD, AND MAGNETIC RECORDING MEDIUM MANFACTURING METHOD

(71) Applicant: SHOWA DENKO K.K., Tokyo (JP)

(72) Inventor: Ichiro OTA, Ichihara-shi (JP)

(73) Assignee: SHOWA DENKO K.K., Tokyo (JP)

(21) Appl. No.: 14/566,105

(22) Filed: Dec. 10, 2014

(30) Foreign Application Priority Data
Dec. 17, 2013 (JP) 2013-260617

(51) Int. Cl. G11B 5/84; C23C 14/06; H01J 37/32; C23C 14/22

(52) U.S. Cl. CPC G11B 5/84; C23C 14/221; C23C 14/0605; H01J 37/3233; H01J 37/32541; H01J 2237/332

(57) ABSTRACT

A carbon film-forming apparatus includes a film forming chamber, a holder that can hold a substrate in the film forming chamber, an introduction pipe that introduces a raw material gas including carbon to the film forming chamber, an ion source that radiates an ion beam to the substrate held by the holder, and a tubular electrode that is provided in an ion acceleration region between the ion source and the holder so as to surround a central axis that connects the center of the ion source and a position corresponding to the center of the substrate held by the holder.

### BACKGROUND OF THE INVENTION

1. Field of the Invention

The present invention relates to a carbon film forming apparatus, a carbon film forming method, and a magnetic recording medium manufacturing method.

Priority is claimed on Japanese Patent Application No. 2013-260617, filed on Dec. 17, 2013, the content of which is incorporated herein by reference.

2. Description of Related Art

In recent years, in the field of magnetic recording media used in, for example, hard disk drives (HDDs), recording density has been remarkably improved and has been continuously increasing at a phenomenal rate of about 1.5 times a year. There are various techniques for improving the recording density. A technique which controls sliding characteristics between a magnetic head and a magnetic recording medium can be exemplified as one of the key technologies.

For example, HDDs of a contact start-stop (CSS) type, known as a Winchester type, and in which a basic operation from the start to the stop of a magnetic head is a contact sliding-floating-contact sliding operation for a magnetic recording medium have been mainly used. Therefore, contact sliding of the magnetic head on the magnetic recording medium is inevitable.

Therefore, problems relating to tribology between the magnetic head and the magnetic recording medium are currently an unavoidable technical issue. There has been a continuous attempt to improve the performance of the protective film formed on the magnetic film of the magnetic recording medium and the abrasion resistance and sliding resistance of the surface of the magnetic recording medium are key factors in improving the reliability of the magnetic recording medium.

Protective films made of various materials have been proposed as the protective film of the magnetic recording medium. However, a carbon film has been mainly used, from the viewpoint of the overall performance, such as film formability and durability.

In addition, for example, the hardness, density, and dynamic friction coefficient of the carbon film are very important since they are vividly reflected in the CSS characteristics or anticorrosion characteristics of the magnetic recording medium.

In order to improve the recording density of the magnetic recording medium, it is preferable to reduce the flying height of the magnetic head and to increase the number of rotations of the magnetic recording medium. Therefore, the protective film formed on the surface of the magnetic recording medium requires high sliding durability or flatness in order to cope with, for example, an accidental contact of the magnetic head. In addition, it is necessary to reduce the thickness of the protective film as much as possible, for example, to a thickness of 30 Å or less, in order to reduce the spacing loss between the magnetic recording medium and the magnetic head and to improve the recording density. There is a strong demand for a protective film smooth, thin, dense, and strong.

In addition, the carbon film, which is used as the protective film of the magnetic recording medium, is formed by using, for example, a sputtering method, a CVD method, or an ion beam deposition method. Among these methods, when the carbon film is formed with a thickness of, for example, 100 Å or less by the sputtering method, the durability of the carbon film is insufficient. On the other hand, when the carbon film formed by the CVD method has low surface smoothness and a small thickness, the coverage of the surface of the magnetic recording medium is reduced, which may cause corrosion of the magnetic recording medium. In contrast, the ion beam deposition method is capable of forming a carbon film with high hardness, smoothness, and dense, as compared to the sputtering method or the CVD method.

As a method of forming a carbon film by using the ion beam deposition method, for example, a method has been proposed in which a raw material gas for film forming is changed into plasma by discharge between a heated filament-shaped cathode and an anode in a film forming chamber in a vacuum atmosphere and the resultant is then accelerated and collides with the surface of a substrate having a negative potential, thereby stably forming a carbon film with high hardness (see Japanese Unexamined Patent Application, First Publication No. 2000-226659).

However, it is necessary to further reduce the thickness of the carbon film in order to further improve the recording density of the magnetic recording medium. It is necessary to manage the thickness of the carbon film on the basis of the thinnest portion of the carbon film formed on the surface of the magnetic recording medium in order to ensure the abrasion resistance or anticorrosion performance of the magnetic recording medium. Therefore, when the thickness distribution of the carbon film formed on the surface of the magnetic recording medium is not constant in the plane, it is difficult to reduce the thickness of the carbon film. In particular, in the method disclosed in Japanese Unexamined Patent Application, First Publication No. 2000-226659, since the filament, excitation source of a carbon gas, extends in one direction, the carbon film deposited on the surface of the substrate has a thickness distribution depending on the shape of the filament.

### SUMMARY OF THE INVENTION

The invention has been made in view of the above-mentioned problems and an object of the invention is to provide a carbon film-forming apparatus which can form a carbon film that has high hardness and density and has a uniform thickness over the wide range of a substrate.

Another object of the invention is to provide a carbon film-forming method which can form a carbon film that has high hardness and density and has a uniform thickness over the wide range of a substrate.

Still another object of the invention is to provide a magnetic recording medium-manufacturing method which uses, as a protective layer of a magnetic recording medium, a carbon film that has high hardness and density and has a uniform thickness over the wide range of a substrate to obtain a magnetic recording medium with high abrasion resistance and corrosion resistance.

In order to achieve the above-mentioned objects, the invention has the following structures.

(1) According to an aspect of the present invention, a carbon film forming apparatus includes: a film forming chamber that can be decompressed; a holder that can hold a substrate in the film forming chamber; an introduction pipe that introduces a raw material gas including carbon to the film forming chamber; an ion source that radiates an ion beam to the substrate held by the holder; and a tubular electrode that is provided in an ion acceleration region between the ion source and the holder so as to surround a central axis that connects the center of the ion source and a position corresponding to the center of the substrate held by the holder.
(2) In the aspect stated in the above (1), the tubular electrode may have a cylindrical shape.
(3) According to an aspect of the present invention, a carbon film-forming method is provided that introduces a raw material gas including carbon into a decompressed film forming chamber, ionizes the gas by using an ion source, accelerates the ionized gas by applying electric field, and radiates the ionized gas to a surface of a substrate to form a carbon film on the surface of the substrate held by a holder. The carbon film-forming method includes: applying a voltage between an anode electrode of the ion source and a tubular electrode, provided in an ion acceleration region between the ion source and the holder so as to surround a central axis that connects the center of the ion source and a position corresponding to the center of the substrate held by the holder, such that a potential of the tubular electrode is positive or negative with respect to a potential of the anode electrode; and applying a voltage between the tubular electrode and the holder such that a potential of the holder is negative with respect to the potential of the tubular electrode.
(4) In the aspect stated in the above (3), a voltage of 50 V to 200 V may be applied between the anode electrode and the tubular electrode such that the potential of the tubular electrode is negative with respect to the potential of the anode electrode.
(5) In the aspect stated in the above (3), a voltage of 50 V to 200 V may be applied between the anode electrode and the tubular electrode such that the potential of the tubular electrode is positive with respect to the potential of the anode electrode.
(6) According to an aspect of the present invention, a magnetic recording medium-manufacturing method includes forming a carbon film on a non-magnetic substrate on which at least a magnetic layer is formed, by using the carbon film-forming method according to the aspect stated in the above any one of (3) to (5).

According to the present invention, it is possible to provide a carbon film forming apparatus which can form a carbon film that has high hardness and density and has a uniform thickness over the wide range of a substrate.

According to the invention, it is possible to provide a carbon film forming method which can form a carbon film that has high hardness and density and has a uniform thickness over the wide range of a substrate.

According to the invention, it is possible to provide a magnetic recording medium manufacturing method which uses, as a protective layer of a magnetic recording medium, a carbon film that has high hardness and density and has a uniform thickness over the wide range of a substrate to obtain a magnetic recording medium with high abrasion resistance and corrosion resistance.

### BRIEF DESCRIPTION OF THE DRAWINGS

FIG. 1 is a diagram schematically showing the structure of a carbon film forming apparatus according to an embodiment of the present invention.

FIGS. 2A, 2B and 2C are schematic diagrams showing the magnetic field applied by a magnet and the direction of magnetic field lines.

FIG. 3 is a cross-sectional view showing an example of a magnetic recording medium manufactured by a manufacturing method according to the present invention.

FIG. 4 is a cross-sectional view showing another example of the magnetic recording medium manufactured by the manufacturing method according to the present invention.

FIG. 5 is a cross-sectional view showing an example of a magnetic recording and reproducing device.

FIG. 6 is a plan view showing the structure of an in-line film forming apparatus according to the present invention.

FIG. 7 is a side view showing a carrier of the in-line film forming apparatus according to the present invention.

FIG. 8 is an enlarged side view showing the carrier shown in FIG. 7; and

FIG. 9 is a graph showing the thickness distribution of a carbon film in a radius direction for bases according to Examples 1 to 3 and Comparative Example 1.

### DETAILED DESCRIPTION OF THE INVENTION

Hereinafter, an embodiment of the invention will be described in detail with reference to the drawings. In the drawings used in the following description, in some cases, a characteristic portion is enlarged for convenience and ease of understanding and the dimensions and ratio of each component may not be the same as the actual dimensions and ratio. In addition, for example, materials and dimensions exemplified in the following description are illustrative examples and the invention is not limited thereto. Various modifications and changes can be made, without departing from the scope and spirit of the invention.

### [Carbon Film Forming Apparatus]

First, a carbon film forming apparatus according to the invention will be described.

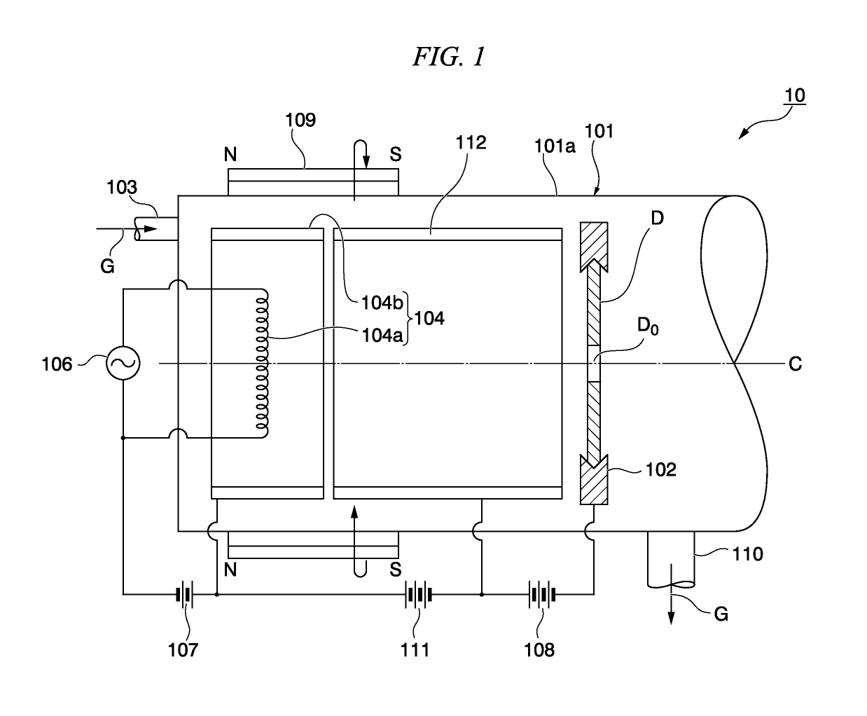

FIG. 1 is a diagram schematically showing the structure of a carbon film forming apparatus according to an embodiment of the invention. FIG. 1 shows a state in which a holder 102 holds a substrate D.

A carbon film forming apparatus 10 shown in FIG. 1 is a film forming apparatus using an ion beam deposition method and has a schematic structure including a film forming chamber (deposition chamber) 101 the inside of which can be decompressed, the holder 102 which can hold the substrate D in the film forming chamber 101, an introduction pipe 103 which introduces a raw material gas G including carbon into the film forming chamber 101, an ion source 104 that radiates an ion beam to the substrate D held by the holder 102, and a tubular electrode 112 provided between the ion source 104 and the holder 102 so as to surround a central axis C that connects the center of the ion source 104 and a position D₀ corresponding to the center of the substrate D held by the holder 102.

In addition, the carbon film-forming apparatus shown in FIG. 1 includes a first power supply 106, a second power supply 107, a third power supply 108, and a fourth power supply 111.

The first power supply 106 is electrically connected a cathode electrode 104a and supplies a current to the cathode electrode 104a for heating.

The second power supply 107 is electrically connected to the cathode electrode 104a and an anode electrode 104b and generates a discharge between the cathode electrode 104a and the anode electrode 104b.

The third power supply 108 is electrically connected to the tubular electrode 112 and the substrate D and applies a voltage between the tubular electrode 112 and the substrate D such that the potential of the substrate D is negative with respect to the potential of the tubular electrode 112. The third power supply 108 may be directly connected to the substrate D or it may be indirectly connected to the substrate D through the holder 102.

The fourth power supply 111 is electrically connected to the anode electrode 104b and the tubular electrode 112 and applies a voltage between the anode electrode 104b and the tubular electrode 112 such that the potential of the tubular electrode 112 is positive or negative with respect to the potential of the anode electrode 104b. FIG. 1 shows an example in which the fourth power supply 111 applies a negative potential to the tubular electrode 112 with respect to the potential of the anode electrode 104b.

The ion source 104 shown in FIG. 1 includes the filament-shaped cathode electrode 104a and the anode electrode 104b provided around the cathode electrode 104a.

The carbon film-forming apparatus shown in FIG. 1 further includes a magnet 109 provided in the outer circumference of a side wall 101a of the film forming chamber 101. The magnet 109 is configured so as to be rotatable about the central axis C that connects the center of the ion source 104 and the position D₀ corresponding to the center of the substrate D held by the holder 102.

It is preferable that the side wall of the film forming chamber have a cylindrical shape. However, the shape of the side wall is not limited to the cylindrical shape. When the side wall has a cylindrical shape, it is preferable that the magnet also have a cylindrical shape. However, the magnet may be formed by a plurality of magnets having a rectangular parallelepiped shape which are arranged so as to surround the side wall.

When the substrate D has a disk shape, it is preferable that the tubular electrode 112 have a cylindrical shape. However, the tubular electrode 112 is not limited to the cylindrical shape. It is preferable that the central axis of the tubular electrode be aligned with the central axis C that connects the center of the ion source 104 and the position D₀ corresponding to the center of the substrate D held by the holder 102. Here, the central axis of the tubular electrode refers to the axis of rotational symmetry when the tubular electrode is rotationally symmetric, as viewed from the direction of the central axis C.

The film forming chamber 101 is formed airtightly by the chamber wall 101a and the inside of the chamber 101 can be decompressed through an exhaust pipe 110 connected to a vacuum pump (not shown).

The first power supply 106 is an AC power supply connected to the cathode electrode 104a and supplies power to the cathode electrode 104a when a carbon film is formed. In addition, the first power supply 106 is not limited to the AC power supply, and may be a DC power supply.

The second power supply 107 is a DC power supply that has a negative electrode connected to the cathode electrode 104a and a positive electrode connected to the anode electrode 104b and generates a discharge between the cathode electrode 104a and the anode electrode 104b when the carbon film is formed.

The third power supply 108 is a DC power supply that has a positive electrode connected to the tubular electrode 112 and a negative electrode connected to the substrate D or the holder 102 and can apply a potential, which is negative with respect to the ion source 104, to the substrate D held by the holder 102 when the carbon film is formed.

In the example shown in FIG. 1, the third power supply 108 and the fourth power supply 111 apply a potential, which is negative with respect to the anode electrode 104b, to the substrate D.

In the example shown in FIG. 1, the fourth power supply 111 is a DC power supply that has a positive electrode connected to the anode electrode 104b and a negative electrode connected to the tubular electrode 112. However, the fourth power supply 111 may be a DC power supply that has a positive electrode connected to the tubular electrode 112 and a negative electrode connected to the anode electrode 104b.

The fourth power supply 111 can apply a potential, which is positive or negative with respect to the anode electrode 104b, to the tubular electrode 112 when the carbon film is formed.

The magnet 109 is a permanent magnet or an electromagnet, is provided around the chamber wall 101a, and can be rotated in a circumferential direction by a driving motor (not shown). When the permanent magnet is used as the magnet 109, it is preferable to use a sintered magnet which can generate a strong magnetic field.

The rotation of the magnet 109 includes the continuous rotation of the magnet in one direction over an angle of 360° and the reciprocating rotation (swinging) of the magnet at an angle of less than 360°. For example, it is possible to uniformize the magnetic field generated in the film forming chamber 101 when a plurality of bar magnets, as the magnet 109, are provided in parallel at equal intervals with respect to the central axis of rotation, an angle between two lines connecting the bar magnets which have the shortest distance therebetween and the central axis is X°, and the angle range of the reciprocating rotation (swinging) of the bar magnets is X°. In addition, when the electromagnet is used, it is preferable to reciprocatively rotate the magnet in an angle range of 180° to 360°, that is equal to or greater than 180° and less than 360°, since it is necessary to supply power.

In the invention, when a carbon film is formed on a disk-shaped substrate with an outside diameter of 3.5 inches, the voltage and current which are generated by each power supply are set as described below. The voltage and current to be generated depend on the size of the substrate D. For the voltage and current applied between two points, which have a heating portion of the cathode electrode 104a therebetween, by the first power supply 106, it is preferable that the voltage be set in the range of 10 V to 100 V and a DC current or an AC current be set in the range of 5 A to 50 A.

For the voltage and current applied between the cathode electrode 104a and the anode electrode 104b by the second power supply 107, it is preferable that the voltage be set in the range of 50 V to 300 V and the current be set in the range of 10 mA to 5000 mA.

For the voltage and current applied between the tubular electrode 112 and the substrate D by the third power supply 108, it is preferable that the voltage be set in the range of 50 V to 500 V and the current be set in the range of 50 mA to 200 mA.

The voltage applied between the anode electrode 104b and the tubular electrode 112 by the fourth power supply 111 is preferably set in the range of 30 V to 400 V and more preferably in the range of 50 V to 200 V in order to improve the stability of the current. It is preferable to set the voltage in the range of 100 V to 180 V in order to reduce a variation in the thickness distribution.

It is preferable that the number of rotations of the magnet 109 be set in the range of, for example, 20 rpm to 200 rpm.

When the carbon film forming apparatus having the above-mentioned structure is used to form a carbon film on the surface of the substrate D, the raw material gas G including carbon is introduced into the film forming chamber 101, the inside of which is decompressed through the exhaust pipe 110, through the introduction pipe 103. The raw material gas G is excited and decomposed by the thermal plasma of the cathode electrode 104a heated by power supplied from the first power supply 106 and the plasma generated by the discharge between the cathode electrode 104a and the anode electrode 104b connected to the second power supply 107 and becomes an ionized gas (carbon ion). Then, the carbon ions excited in the plasma collide with the surface of the substrate D while being accelerated to the substrate D with a negative potential by the third power supply 108 and the fourth power given by using supply 111.

In the carbon film forming apparatus according to this embodiment, the tubular electrode 112 can apply the electric field which has an effect on the spreading of the ion beams in a direction perpendicular to the traveling direction of the ion beams in a region (ion acceleration region) in which the gas obtained by ionizing the raw material gas G is accelerated.

In the carbon film forming apparatus according to this embodiment, when the carbon ions are accelerated and radiated to the surface of the substrate D, a negative voltage is applied between the tubular electrode 112 and the anode electrode 104b such that the potential of the tubular electrode 112 is lower than the potential of the anode electrode 104b. Therefore, the carbon ion beams which are accelerated and radiated to the surface of the substrate D are drawn to the tubular electrode 112 and the spreading of the carbon ion beams is more than that when the above-mentioned voltage is not applied between the tubular electrode 112 and the anode electrode 104b. It is possible to adjust the spreading of the carbon ion beams, depending on the level of the voltage applied between the tubular electrode 112 and the anode electrode 104b. The adjustment of the spreading of the carbon ion beams enables a sufficient number of carbon ions to be incident on the edge of the substrate, as compared to when the above-mentioned voltage is not applied between the tubular electrode 112 and the anode electrode 104b. The adjustment of the level of the voltage applied between the tubular electrode 112 and the anode electrode 104b makes it possible to uniformize the thickness distribution of the carbon film and to manufacture the substrate D having a uniform thickness distribution of the carbon film at the edge of the surface thereof.

When the carbon ions are accelerated and radiated to the surface of the substrate D, a positive voltage is applied between the tubular electrode 112 and the anode electrode 104b such that the potential of the tubular electrode 112 is higher than the potential of the anode electrode 104b. Therefore, the carbon ion beams, which are accelerated and radiated to the surface of the substrate D, are converged on the central axis of the tubular electrode 112 by electric force and the spreading of the carbon ion beams is less than that when the above-mentioned voltage is not applied between the tubular electrode 112 and the anode electrode 104b. In this case, it is possible to uniformize the thickness distribution of the carbon film on a substrate with a small diameter and to manufacture the substrate D having a uniform thickness distribution of the carbon film at the edge of the surface thereof.

When the carbon film-forming apparatus according to the invention is used to form a carbon film, the magnet 109, which is provided around the chamber wall 101a, may be used to apply the magnetic field to a region in which the raw material gas G is ionized or a region (hereinafter, referred to as an excitation space) in which the ionized gas (ion beam) is accelerated.

When the carbon ions are accelerated and radiated to the surface of the substrate D, the magnetic field may be applied from the outside to increase the density of the carbon ions which are accelerated and radiated to the surface of the substrate D. In this case, when the ion density increases in the excitation space, an excitation force in the excitation space is strengthened and carbon ions with a higher energy level can be accelerated and radiated to the surface of the substrate D. As a result, it is possible to form a carbon film with high hardness and density on the surface of the substrate D.

In addition, since the magnet 109 provided around the excitation space is rotated in the circumferential direction, it is possible to uniformize the distribution of the magnetic field applied to the excitation space, to uniformize the distribution of the carbon ions in the excitation space, and to radiate the carbon ions to the surface of the substrate D. Therefore, it is possible to uniformize the thickness distribution of the carbon film formed on the surface of the substrate D.

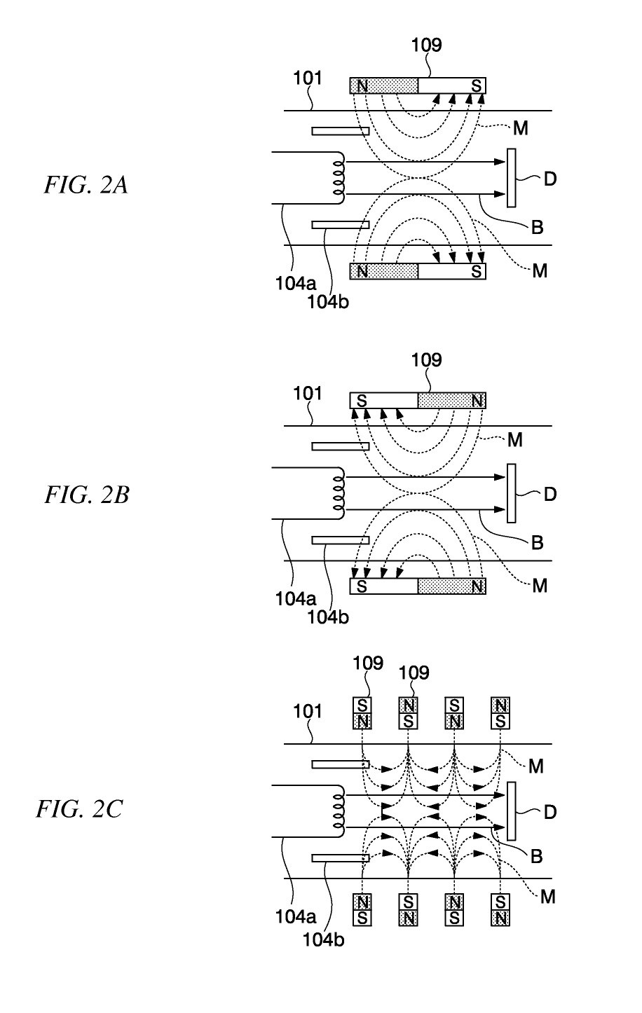

For example, the structures shown in FIGS. 2A to 2C can be used for the magnetic field applied by the magnet 109 and the direction of magnetic field lines.

That is, in the structure shown in FIG. 2A (the same structure as that shown in FIG. 1), the magnet 109 is arranged around the chamber wall 101a of the film forming chamber 101 such that the S-pole is close to the substrate D and the N-pole is close to the cathode electrode 104a. In this structure, magnetic field lines M, which are generated by the magnet 109, are substantially parallel to the acceleration direction of an ion beam B in the vicinity of the center of the film forming chamber 101. When the magnetic field lines M are set in the above-mentioned direction in the film forming chamber 101, it is possible to concentrate the carbon ions in the excitation space on the vicinity of the center of the film forming chamber 101 using magnetic moment and to effectively increase the density of ions in the excitation space.

In the structure shown in FIG. 2B, the magnet 109 is arranged around the chamber wall 101a of the film forming chamber 101 such that the S-pole is close to the cathode electrode 104a and the N-pole is close to the substrate D. In the structure shown in FIG. 2C, a plurality of magnets 109 are arranged around the chamber wall 101a of the film forming chamber 101 such that the directions of the N-pole and the S-pole are alternately changed on the inner circumferential side and the outer circumferential side in the acceleration direction of the ion beam B, that is, the magnetic poles facing the chamber wall 101a are alternately changed. In all of the structures, the magnetic field lines M generated by the magnet 109 are substantially parallel to the acceleration direction of the ion beam B in the vicinity of the center of the film forming chamber 101. Therefore, it is possible to effectively increase the density of ions in the excitation space.

It is preferable to use a sintered magnet in order to generate a strong magnetic field. However, when the sintered magnet is used as the magnet 109, it is difficult to manufacture a large magnet 109. Therefore, a plurality of magnets 109 are arranged around the chamber wall 101a. In this case, the magnetic field generated by the plurality of magnets 109 arranged around the chamber wall 101a is not necessarily constant (symmetric) in the excitation space. Therefore, in the invention, the plurality of magnets 109 arranged around the chamber wall 101a are rotated in the circumferential direction to uniformize the magnetic field distribution in the excitation space.

When the magnet 109 is an electromagnet, the distribution of the magnetic field generated varies depending on a method of winding coils on a magnetic core in the electromagnet. Therefore, the magnet 109, an electromagnet, can be rotated in the circumferential direction to uniformize the magnetic field distribution in the excitation space.

In the carbon film forming apparatus shown in FIG. 1, the carbon film is formed on only one surface of the substrate D. However, the carbon film may be formed on both surfaces of the substrate D. In this case, the same apparatus structure as that when the carbon film is formed on only one surface of the substrate D may be provided on both sides of the substrate D in the film forming chamber 101.

### [Carbon Film Forming Method]

A carbon film forming method according to an embodiment of the invention introduces a raw material gas including carbon into a decompressed film forming chamber, ionizes the gas by using an ion source, accelerates the ionized gas by applying electric field, radiates the ionized gas to a surface of a substrate to form a carbon film on the surface of the substrate held by a holder. In the carbon film-forming method, a tubular electrode is provided between the ion source and the holder so as to surround a central axis that connects the center of the ion source and a position corresponding to the center of the substrate held by the holder. A voltage that is positive or negative with respect to the potential of an anode electrode of the ion source is applied to the tubular electrode and a voltage that is negative with respect to the potential of the tubular electrode is applied to the holder to form the carbon film.

In the following description, reference numerals which follow components correspond to the reference numerals described in the drawings.

In the carbon film forming method according to the invention, for example, gas including a hydrocarbon can be used as the raw material gas G including carbon. One or two or more kinds of lower hydrocarbons among lower saturated hydrocarbons, lower unsaturated hydrocarbons, and lower cyclic hydrocarbons are preferably used as the hydrocarbon. The term “lower” indicates a case in which a carbon number is 1 to 10.

Among them, for example, methane, ethane, propane, butane, and octane can be used as the lower saturated hydrocarbon. For example, isoprene, ethylene, propylene, butylene, and butadiene can be used as the lower unsaturated hydrocarbon. For example, benzene, toluene, xylene, styrene, naphthalene, cyclohexane, and cyclohexadiene can be used as the lower cyclic hydrocarbon.

In the invention, it is preferable to use the lower hydrocarbon for the following reason: when the carbon number in a hydrocarbon is beyond the above-mentioned range, it is difficult to supply the lower hydrocarbon as gas from the introduction pipe 103, a hydrocarbon is hard to be decomposed during discharge, and the carbon film includes a large number of polymer components having low strength.

In the invention, a mixed gas including, for example, inert gas or hydrogen gas may be used as the raw material gas G including carbon in order to generate plasma in the film forming chamber 101. The mixture ratio of hydrocarbon to inert gas in the mixed gas is preferable set in the range of 2:1 to 1:100 (volume ratio).

The carbon film forming method according to the invention can perform the following processes, using a film forming apparatus in which the tubular electrode is provided between the ion source and the holder so as to surround the central axis that connects the center of the ion source and the position corresponding to the center of the substrate held by the holder, to form a carbon film having a more uniform thickness than that in the related art: the raw material gas G including carbon is introduced into the decompressed film forming chamber 101; the raw material gas G is ionized by the discharge between the filament-shaped cathode electrode 104a supplied with a current and heated and the anode electrode 104b provided around the cathode electrode 104a; a voltage that is negative or positive with respect to the potential of the anode electrode of the ion source is applied to the tubular electrode and a voltage that is negative with respect to the potential of the tubular electrode is applied to the holder when the ionized gas is accelerated and radiated to the surface of the substrate D; and the levels of the voltages are adjusted such that the spreading of the ion beams matches the size of the substrate.

In the carbon film-forming method according to the invention, when the carbon ions are accelerated and radiated to the surface of the substrate, a negative voltage is applied between the tubular electrode and the anode electrode such that the potential of the tubular electrode is lower than the potential of the anode electrode. Then, the carbon ion beams which are accelerated and radiated to the surface of the substrate are drawn to the tubular electrode and the spreading of the carbon ion beams is more than that when no voltage is applied between the tubular electrode and the anode electrode. That is, the spreading of the carbon ion beams can be adjusted by the level of the voltage applied between the tubular electrode and the anode electrode. The adjustment of the spreading of the carbon ion beams enables a sufficient number of carbon ions to be incident on the edge of the substrate, as compared to when no voltage is applied between the tubular electrode and the anode electrode. The adjustment of the level of the voltage applied between the tubular electrode and the anode electrode makes it possible to uniformize the thickness distribution of the carbon film and to manufacture a substrate having a uniform thickness distribution of the carbon film at the edge of the surface thereof.

When the carbon ions are accelerated and radiated to the surface of the substrate, a positive voltage is applied between the tubular electrode and the anode electrode such that the potential of the tubular electrode is higher than the potential of the anode electrode. Then, the carbon ion beams which are accelerated and radiated to the surface of the substrate are converted onto the central axis of the tubular electrode by electric force and the spreading of the carbon ion beams is less than that when no voltage is applied between the tubular electrode and the anode electrode. In this case, the thickness distribution of the carbon film is uniformized on a substrate with a small diameter and it is possible to manufacture the substrate D having a uniform thickness distribution of the carbon film at the edge of the surface thereof.

In the carbon film-forming method according to the invention, the magnet 109 arranged around the chamber wall 101a may be used to apply the magnetic field to a region in which the raw material gas G is ionized or a region (hereinafter, referred to as an excitation space) in which the ionized gas (ion beam) is accelerated.

When the carbon ions are accelerated and radiated to the surface of the substrate D, the magnetic field can be applied from the outside to increase the density of the carbon ions which are accelerated and radiated to the surface of the substrate D. When the ion density in the excitation space increases, excitation force in the excitation space is strengthened and it is possible to accelerate and radiate carbon ions with a higher energy level to the surface of the substrate D. As a result, it is possible to form a carbon film with high hardness and density on the surface of the substrate D.

When the magnet 109 arranged around the excitation space is rotated in the circumferential direction, the distribution of the magnetic field applied to the excitation space is uniformized and the distribution of the carbon ions in the excitation space is uniformized. It is possible to radiate the carbon ions with a uniform distribution to the surface of the substrate D. Therefore, it is possible to uniformize the thickness distribution of the carbon film formed on the surface of the substrate D.

### (Magnetic Recording Medium-Manufacturing Method)

Next, a magnetic recording medium-manufacturing method according to the invention will be described.

In this embodiment, an example will be described in which a magnetic recording medium provided in a hard disk device is manufactured by an in-line film-forming apparatus that performs a film-forming process while sequentially transporting the substrate, on which a film will be formed, between a plurality of film forming chambers.

### (Magnetic Recording Medium)

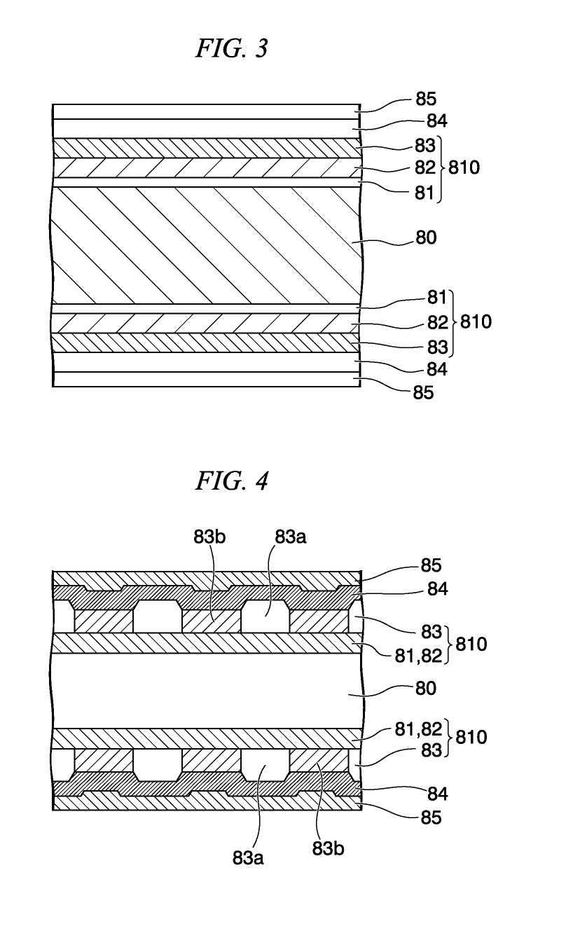

For example, as shown in FIG. 3, the magnetic recording medium manufactured by the manufacturing method according to the invention has a structure in which soft magnetic layers 81, intermediate layers 82, recording magnetic layers 83, and protective layers 84 are sequentially formed on both surfaces of a non-magnetic substrate 80 and lubrication films 85 are formed on the outermost surfaces. The soft magnetic layer 81, the intermediate layer 82, and the recording magnetic layer 83 form a magnetic layer 810.

In the magnetic recording medium, as the protective layer 84, a carbon film with high hardness and density is formed with a uniform thickness by the carbon film-forming method according to the invention. In this case, in the magnetic recording medium, it is possible to reduce the thickness of the carbon film. Specifically, it is possible to reduce the thickness of the carbon film to about 2 nm or less.

Therefore, in the invention, it is possible to set a distance between the magnetic recording medium and a magnetic head to a small value. As a result, it is possible to increase the recording density of the magnetic recording medium and to improve the anticorrosion performance of the magnetic recording medium.

Next, layers other than the protective layer 84 of the magnetic recording medium will be described.

Any non-magnetic substrates, such as an Al alloy substrate made of, for example, an Al—Mg alloy having Al as a main component or substrates made of general soda glass, aluminosilicate-based glass, crystallized glasses, silicon, titanium, ceramics, and various kinds of resins, can be used as the non-magnetic substrate 80.

Among them, it is preferable to use an Al alloy substrate, a substrate made of glass, such as crystallized glass, or a silicon substrate. The average surface roughness (Ra) of the substrate is preferably equal to or less than 1 nm, more preferably equal to or less than 0.5 nm, and most preferably equal to or less than 0.1 nm.

The magnetic layer 810 may be an in-plane magnetic layer for an in-plane magnetic recording medium or a vertical magnetic layer for a vertical magnetic recording medium. It is preferable to use the vertical magnetic layer in order to increase the recording density. It is preferable that the magnetic layer 810 be made of an alloy having Co as a main component. For example, a laminate of the soft magnetic layer 81 made of, a FeCo alloy (FeCoB, FeCoSiB, FeCoZr, FeCoZrB, FeCoZrBCu, or the like), a FeTa alloy (FeTaN, FeTaC, or the like), or a Co alloy (CoTaZr, CoZrNB, CoB, or the like), the intermediate layer 82 made of, for example, Ru, and the recording magnetic layer 83 made of a 60Co-15Cr-15Pt alloy or a 70Co-5Cr-15Pt-10SiO₂ alloy can be used as the magnetic layer 810 for a vertical magnetic recording medium. An orientation control film made of, for example, Pt, Pd, NiCr, or NiFeCr may be provided between the soft magnetic layer 81 and the intermediate layer 82. A laminate of a non-magnetic CrMo base layer and a CoCrPtTa ferromagnetic layer can be used as the magnetic layer 810 for an in-plane magnetic recording medium.

The overall thickness of the magnetic layer 810 is equal to or greater than 3 nm and equal to or less than 20 nm and preferably equal to or greater than 5 nm and equal to or less than 15 nm. The magnetic layer 810 may be formed, depending on the magnetic alloy and stacking structure used, such that sufficient head output and input are obtained. The magnetic layer 810 needs to have a thickness equal to or greater than a predetermined value in order to obtain an output equal to or greater than a predetermined value during reproducing. In general, parameters indicating recording and reproducing characteristics deteriorate with an increase in output. Therefore, it is necessary to set the thickness of the magnetic layer 810 to an optimum value.

A fluorinated liquid lubricant made of, for example, perfluoropolyether (PFPE) or a solid lubricant made of, for example, a fatty acid can be used as a lubricant for the lubrication film 85. In general, the lubrication layer 85 is formed with a thickness of 1 nm to 4 nm. A known method, such as a dipping method or a spin-coating method, may be used as a method for applying the lubricant.

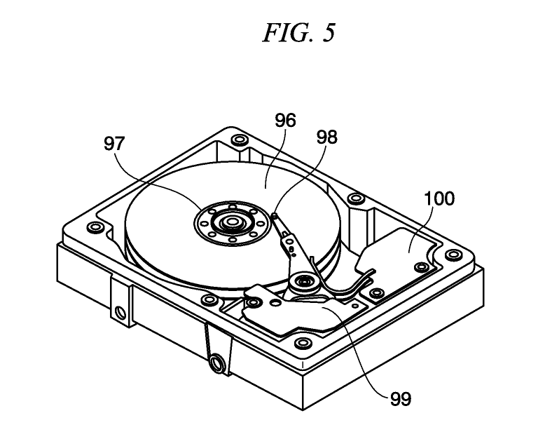

As another magnetic recording medium manufactured by the manufacturing method according to the invention, for example, a so-called discrete magnetic recording medium may be used in which magnetic recording patterns 83a formed in the recording magnetic layer 83 are separated from each other by non-magnetic regions 83b, as shown in FIG. 4.

Examples of the discrete magnetic recording medium include so-called patterned media in which the magnetic recording patterns 83a are regularly arranged for one bit, media in which the magnetic recording patterns 83a are arranged in a track shape, and other media in which the magnetic recording pattern 83a includes, for example, a servo signal pattern.

The discrete magnetic recording medium is obtained by providing a mask layer on the surface of the recording magnetic layer 83 and by performing a reactive plasma process or an ion irradiation process on a portion of the recording magnetic layer 83 that is not covered with the mask layer to modify the portion of the recording magnetic layer 83 from a magnetic body to a non-magnetic body, thereby forming the non-magnetic region 83b.

### (Magnetic Recording and Reproducing Device)

For example, a hard disk device shown in FIG. 5 can be given as an example of a magnetic recording and reproducing device using the above-mentioned magnetic recording medium. The hard disk device includes a magnetic disk 96 (the above-mentioned magnetic recording medium), a medium-driving unit 97 which rotates the magnetic disk 96, a magnetic head 98 which records information on the magnetic disk 96 and reproduces information from the magnetic disk, a head-driving unit 99, and a recording and reproducing signal-processing system 100. The magnetic reproducing signal-processing system 100 processes input data, transmits a recording signal to the magnetic head 98, processes a reproduction signal from the magnetic head 98, and outputs data.

### (In-Line Film Forming Apparatus)

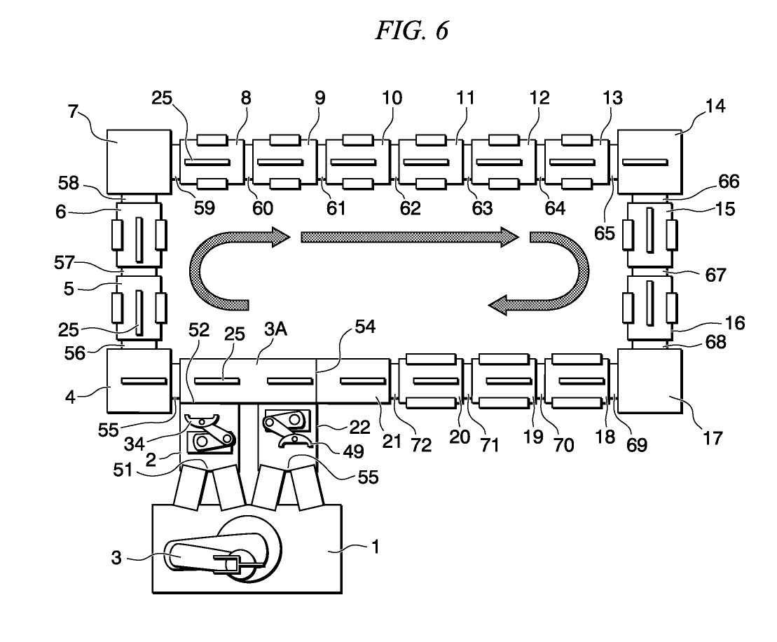

For example, when the above-mentioned magnetic recording medium is manufactured, the in-line film forming apparatus (magnetic recording medium-manufacturing apparatus) according to the invention shown in FIG. 6 is used to sequentially form the magnetic layers 810, each including at least the soft magnetic layer 81, the intermediate layer 82, and the recording magnetic layer 83, and the protective layers 84 on both surfaces of the non-magnetic substrate 80, on which films will be formed. Therefore, it is possible to stably manufacture the magnetic recording medium having a carbon film with high hardness and density as the protective layer 84.

Specifically, the in-line film forming apparatus according to the invention has a schematic structure including a robot stand 1, a substrate cassette transfer robot 3 placed on the robot stand 1, a substrate supply robot chamber 2 adjacent to the robot stand 1, a substrate supply robot 34 installed in the substrate supply robot chamber 2, a substrate attachment chamber 52 adjacent to the substrate supply robot chamber 2, corner chambers 4, 7, 14, and 17 which rotate a carrier 25, processing chambers 5, 6, 8 to 13, 15, 16, and 18 to 21 which are provided between the corner chambers 4, 7, 14, and 17, a substrate detachment chamber 54 provided adjacent to the processing chamber 20, a chamber 3A integrated with the substrate attachment chamber 52, a substrate detachment robot chamber 22 provided adjacent to the substrate detachment chamber 54, a substrate detachment robot 49 installed in the substrate detachment robot chamber 22, and a plurality of carriers 25 which are transported between the chambers.

Each of the chambers 2, 52, 4 to 21, 54, and 3A is connected to two adjacent walls and gate valves 55 to 71 are provided in connection portions between the chambers 2, 52, 4 to 21, 54, and 3A. When the gate valves 55 to 71 are closed, the inside of each chamber is an independent closed space.

Vacuum pumps (not shown) are connected to the chambers 2, 52, 4 to 21, 54, and 3A and the inside of each chamber can be decompressed by the operation of the vacuum pump. The soft magnetic layer 81, the intermediate layer 82, the recording magnetic layer 83, and the protective layer 84 are sequentially formed on both surfaces of the non-magnetic substrate 80 mounted on the carrier 25 in the depressurized chambers while the carrier 25 is sequentially transported between the chambers by a transport mechanism (not shown). In this way, the in-line film forming apparatus according to the invention is configured such that the magnetic recording medium shown in FIG. 3 is finally obtained. The corner chambers 4, 7, 14, and 17 are chambers for changing the moving direction of the carrier 25. A mechanism which rotates the carrier 25 and moves the carrier 25 to the next chamber is provided in each of the corner chambers 4, 7, 14, and 17.

The substrate cassette transfer robot 3 supplies the non-magnetic substrate 80 from a cassette that stores the non-magnetic substrates 80 before deposition to the substrate attachment chamber 2 and takes out the non-magnetic substrate 80 (magnetic recording medium) after deposition detached in the substrate detachment chamber 22. Openings which are exposed to the outside and doors 51 and 55 which open or close the openings are provided in one side wall of each of the substrate attachment chamber 2 and the substrate detachment chamber 22.

In the substrate attachment chamber 52, the non-magnetic substrate 80 before deposition is mounted on the carrier by using the substrate supply robot 34. In the substrate detachment chamber 54, the non-magnetic substrate 80 (magnetic recording medium) after deposition mounted on the carrier 25 is detached by using the substrate detachment robot 49. The carrier 25 transported from the substrate detachment chamber 54 is transported to the substrate attachment chamber 52.

Among the processing chambers 5, 6, 8 to 13, 15, 16, and 18 to 21, a plurality of film forming chambers for forming the magnetic layer 810 are formed by the processing chambers 5, 6, 8 to 13, 15, and 16. The film forming chambers include a mechanism for forming the soft magnetic layer 81, the intermediate layer 82, and the recording magnetic layer 83 on both surfaces of the non-magnetic substrate 80.

The processing chambers 18 to 20 form a film forming chamber for forming the protective layer 84. The film forming chamber has the same apparatus structure as the film-forming apparatus using the ion beam deposition method shown in FIG. 1 and forms a carbon film with high hardness and density as the protective layer 84 on the surface of the non-magnetic substrate 80 on which the magnetic layer 810 is formed.

When the magnetic recording medium shown in FIG. 4 is manufactured, the processing chambers may further include a patterning chamber for patterning a mask layer on the recording magnetic layer 83, a modifying chamber for performing a reactive plasma process or an ion irradiation process on a portion of the recording magnetic layer 83 not covered with the patterned mask layer to modify the portion of the recording magnetic layer 83 from a magnetic body to a non-magnetic body, thereby forming the magnetic recording patterns 83a separated by the non-magnetic regions 83b, and a removal chamber for removing the mask layer.

A processing gas supply pipe is provided in each of the processing chambers 5, 6, 8 to 13, 15, 16, and 18 to 21. A valve opened and closed under the control of a control mechanism (not shown) is provided in the supply pipe. The valves and the pump gate valves are opened and closed to control the supply of gas from the processing gas supply pipe, the internal pressure of the chamber, and the discharge of gas.

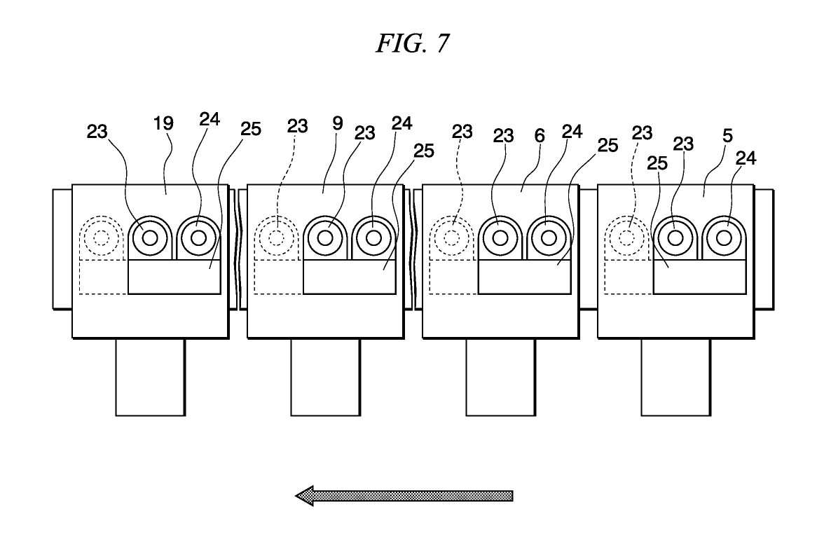

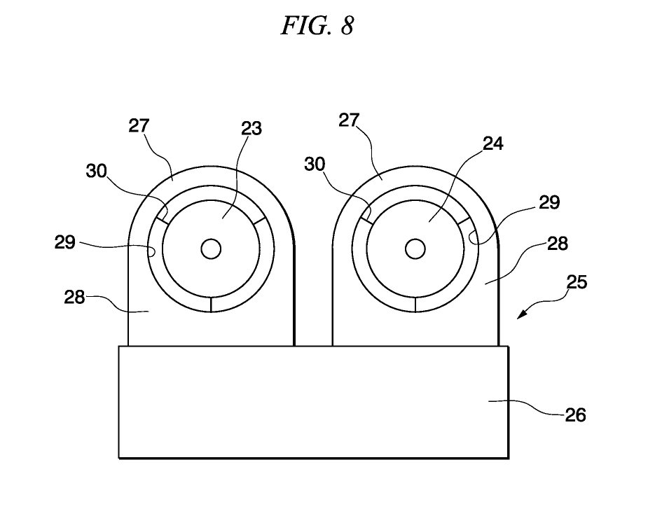

As shown in FIGS. 7 and 8, the carrier 25 includes a support 26 and a plurality of substrate-mounting portions 27 which are provided on the upper surface of the support 26. In this embodiment, the support 26 is configured such that two substrate-mounting portions 27 can be mounted on the support 26. Therefore, two non-magnetic substrates 80 which are mounted on the substrate-mounting portions 27 are referred to as a first film-forming substrate 23 and a second film-forming substrate 24.

The substrate-mounting portion 27 has a thickness that is about equal to or several times greater than the thickness of the first and second film-forming substrates 23 and 24 and includes a plate body 28 in which a through hole 29 is formed in a thickness direction and a plurality of supporting members 30 which protrude inward from the circumferential edge of the through hole 29 in the thickness direction in a plane view. The through hole 29 has a circular shape and a diameter that is slightly greater than that of the film-forming substrates 23 and 24. In the substrate-mounting portions 27, the first and second film-forming substrates 23 and 24 are inserted into the through holes 29 and the circumference thereof is fitted to the supporting members 30. Therefore, the first and second film-forming substrates 23 and 24 are vertically held (the main surfaces of the substrates 23 and 24 are parallel to the direction of gravity). That is, in the substrate-mounting portion 27, the mounted first and second film-forming substrates 23 and 24 are provided on the upper surface of the support 26 in parallel such that the main surfaces thereof are substantially orthogonal to the upper surface of the support 26 and are substantially flush with each other.

In the processing chambers 5, 6, 8 to 13, 15, 16, and 18 to 21, two processing devices are provided on both sides of the carrier 25. In this case, for example, with the carrier 25 stopped at a first processing position represented by a solid line in FIG. 7, for example, a deposition process can be performed on the first film-forming substrate 23 provided on the left side in the carrier 25. Then, the carrier 25 can be moved to a second processing position represented by a dashed line in FIG. 7. With the carrier 25 stopped at the second processing position, for example, a deposition process can be performed on the second film-forming substrate 24 provided on the right side in the carrier 25.

When four processing devices are provided on both sides of the carrier 25 so as to face the first and second film-forming substrates 23 and 24, it is not necessary to move the carrier 25 and, for example, a deposition process can be performed on the first and second film-forming substrates 23 and 24 held by the carrier 25 at the same time.

### EXAMPLES

Hereinafter, the effects of the invention will become apparent from the following examples. The invention is not limited to the following examples and can be appropriately changed, without departing from the scope and spirit of the invention.

### Example 1

In Example 1, a base (substrate) including a carbon film (protective film) in a magnetic recording medium was manufactured by the carbon film forming apparatus and the carbon film forming method according to the invention and the magnetic recording medium manufacturing method according to the invention.

First, a NiP-plated aluminum substrate was prepared as a non-magnetic substrate. Then, the in-line film forming apparatus shown in FIG. 6 was used to sequentially form a soft magnetic layer which was made of FeCoB and had a thickness of 60 nm, an intermediate layer which was made of Ru and had a thickness of 10 nm, and a recording magnetic layer which was made of a 70Co-5Cr-15Pt-10SiO₂ alloy and had a thickness of 15 nm on both surfaces of the non-magnetic substrate mounted on a carrier which was made of an aluminum alloy (A5052), thereby forming magnetic layers. Then, the non-magnetic substrate mounted on the carrier was transported to a processing chamber having the same structure as the film forming apparatus shown in FIG. 1 and protective layers which were carbon films were formed on both surfaces of the non-magnetic substrate having the magnetic layers formed thereon.

Specifically, the processing chamber has a cylindrical shape with an outside diameter of 180 mm and a length of 250 mm and the wall of the processing chamber is made of SUS304. A coil-shaped cathode electrode made of tantalum and has a length of about 30 mm and a cylindrical anode electrode which surrounds the cathode electrode are provided in the processing chamber. The anode electrode is made of SUS304 and has an inside diameter of 140 mm and a length of 40 mm. The distance between the cathode electrode and the non-magnetic substrate was 160 mm. In addition, a cylindrical magnet was provided so as to surround the wall of the chamber and the anode electrode was disposed at the center of the cylindrical magnet. The magnet has an inside diameter of 185 mm and a length of 40 mm. As shown in FIG. 2A, 20 NdFe-based sintered bar magnets which had a size of 10 mm square and a length of 40 mm were arranged in parallel at equal intervals in the cylindrical magnet. Each of the sintered bar magnets was arranged such that the S-pole of each magnet was close to the substrate and the N-pole of each magnet was close to the cathode electrode. The total magnetic force of the magnets is 50 G (5 mT). While the carbon film was being formed, the magnet was rotated at 100 rpm. The tubular electrode is made of SUS304 and has an inside diameter of 140 mm and a length of 110 mm. The tubular electrode was arranged such that the central axis thereof was aligned with a central axis which connects the center of the ion source and a position corresponding to the center of the substrate held by the holder.

Toluene gas was used as a raw material gas. The carbon film was formed under the following conditions: a gas flow rate of 2.9 SCCM; a reaction pressure of 0.2 Pa; a cathode power of 225 W (AC 22.5 V, 10A); a voltage between the cathode electrode and the anode electrode was 75 V; a current between the cathode electrode and the anode electrode was 1650 mA; the voltage of the tubular electrode with respect to the anode electrode was −75 V; an ion acceleration voltage of 200 V; an ion acceleration current of 180 mA; and a deposition time of 1.5 seconds.

### Example 2

In Example 2, a base (substrate) was manufactured under the same conditions as those in Example 1 except that the voltage of the tubular electrode with respect to the anode electrode was −150 V.

### Example 3

In Example 3, a base was manufactured under the same conditions as those in Example 1 except that the voltage of the tubular electrode with respect to the anode electrode was −200 V.

### Comparative Example 1

A carbon film-forming apparatus used in Comparative Example 1 differs from the carbon film-forming apparatus used in the examples in that it does not include the tubular electrode. Therefore, a base was manufactured under the same carbon film-forming conditions as those in Example 1 except that there was no electric field generated by the tubular electrode.

### (Evaluation of Thickness Distribution of Carbon Film)

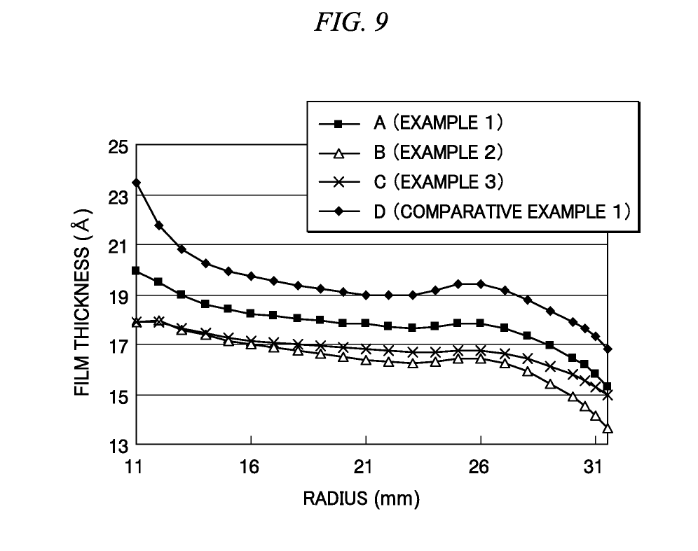

FIG. 9 is a graph showing the thickness distribution of the carbon film in a radius direction for the bases according to Examples 1 to 3 and Comparative Example 1. The horizontal axis indicates the distance (hereinafter, referred to as a “radius position”) from the center of the base in the radius direction. A radius position of 11 mm indicates an inner circumferential position and a radius position of 31 mm indicates an outer circumferential position. The vertical axis indicates the thickness in each radius position.

In FIG. 9, letters A, B, C, and D correspond to the bases according to Examples 1 to 3 and Comparative Example 1, respectively.

As shown in FIG. 9, in Comparative Example 1, the thickness of an inner circumferential portion was significantly greater than the thickness of a central portion (in the vicinity of the radius position of 21 mm). Specifically, while the thickness at the radius position of 21 mm was 1.9 nm, the thickness at the radius position of 11 mm was 2.35 nm. The difference between the thicknesses was equal to or greater than 0.4 nm. The difference between the thicknesses corresponds to 20% or more of the thickness at the radius position of 21 mm and the thickness distribution is very wide.

In contrast, in Examples 1 to 3, the difference between the thickness of the central portion and the thickness of the inner circumferential portion is small. Specifically, in Example 1, while the thickness at the radius position of 21 mm was 1.8 nm, the thickness at the radius position of 11 mm was 2.0 nm. The difference between the thicknesses was 0.3 nm. In Example 2, while the thickness at the radius position of 21 mm was 1.65 nm, the thickness at the radius position of 11 mm was 1.8 nm. The difference between the thicknesses was 0.15 nm. In Example 3, while the thickness at the radius position of 21 mm was 1.7 nm, the thickness at the radius position of 11 mm was 1.8 nm. The difference between the thicknesses was 0.1 nm.

As described above, in Examples 1 to 3, the difference between the thickness in the vicinity of the inner circumferential portion and the thickness of the central portion was less than that in Comparative Example 1 and a variation in the thickness distribution was reduced. The reduction in Examples 2 and 3 was larger than that in Example 1. Therefore, for the voltage of the tubular electrode with respect to the anode electrode, −150 V to −200 V is preferable to −75 V.

In all of Examples 1 to 3, the thickness was less than that in Comparative Example 1. This is probably due to the spreading of the carbon ion beams by the electric field generated by the tubular electrode. It is possible to increase the thickness by increasing the deposition time.

According to the invention, it is possible to provide a carbon film forming apparatus, a carbon film forming method, and a magnetic recording medium manufacturing method which can improve the uniformity of the thickness of a carbon film with high hardness and density.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

### REFERENCE SIGNS LIST

10 Carbon film forming apparatus
101 Film forming chamber (Deposition chamber)
102 Holder
103 Introduction pipe
104 Ion source
112 Tubular electrode
D Substrate

What is claimed is:

1. A carbon film forming apparatus, comprising:
a film forming chamber;
a holder that can hold a substrate in the film forming chamber;
an introduction pipe that introduces a raw material gas including carbon to the film forming chamber;
an ion source that radiates an ion beam to the substrate held by the holder; and
a tubular electrode that is provided in an ion acceleration region between the ion source and the holder so as to surround a central axis that connects the center of the ion source and a position corresponding to the center of the substrate held by the holder.

2. The carbon film forming apparatus according to claim 1,
wherein the tubular electrode has a cylindrical shape.

3. A carbon film forming method that introduces a raw material gas including carbon into a decompressed film forming chamber, ionizes the gas by using an ion source, accelerates the ionized gas by applying electric field, and radiates the ionized gas to a surface of a substrate to form a carbon film on the surface of the substrate held by a holder, comprising:
applying a voltage between an anode electrode of the ion source and a tubular electrode, which is provided in an ion acceleration region between the ion source and the holder so as to surround a central axis that connects the center of the ion source and a position corresponding to the center of the substrate held by the holder, such that a potential of the tubular electrode is positive or negative with respect to a potential of the anode electrode; and
applying a voltage between the tubular electrode and the holder such that a potential of the holder is negative with respect to the potential of the tubular electrode.

4. The carbon film forming method according to claim 3,
wherein a voltage of 50 V to 200 V is applied between the anode electrode and the tubular electrode such that the potential of the tubular electrode is negative with respect to the potential of the anode electrode.

5. The carbon film forming method according to claim 3,
wherein a voltage of 50 V to 200 V is applied between the anode electrode and the tubular electrode such that the potential of the tubular electrode is positive with respect to the potential of the anode electrode.

6. A magnetic recording medium manufacturing method, comprising:
forming a carbon film on a non-magnetic substrate on which at least a magnetic layer is formed, by using the carbon film forming method according to claim 3.
